(19) United States
(12) Patent Application Publication
(10) Pub. No.: US 2017/0338409 A1
(43) Pub. Date: Nov. 23, 2017

(54) SWITCHING ELEMENT, RESISTIVE MEMORY DEVICE INCLUDING SWITCHING ELEMENT, AND METHODS OF MANUFACTURING THE SAME

(71) Applicant: SK hynix Inc., Icheon (KR)

(72) Inventors: Jong Chul LEE, Icheon (KR); Kyung Wan KIM, Icheon (KR)

(21) Appl. No.: 15/402,125

(22) Filed: Jan. 9, 2017

(30) Foreign Application Priority Data
May 18, 2016 (KR) 10-2016-0061099

(51) Int. Cl. H01L 45/00; H01L 27/24

(52) U.S. Cl. CPC H01L 45/10; H01L 27/2463; H01L 45/1233

(57) ABSTRACT

A method of manufacturing a switching element includes forming a pillar-shaped structure over a substrate, performing a dopant injection process to form a first doping region in an insulation layer. The method further includes performing the dopant injection process to form a second doping region in a first electrode, to form a third doping region in a second electrode, or both. The pillar-shaped structure includes the first electrode, the insulation layer, and the second electrode that are disposed over a substrate. The first and second doping regions form a first interface therebetween, and the first and third doping regions form a second interface therebetween. The first doping region corresponds to a region in which a threshold switching operation region is performed.

### CROSS-REFERENCE TO RELATED APPLICATION

The present application claims priority under 35 U.S.C. 119(a) to Korean Patent Application No. 10-2016-0061099, filed on May 18, 2016L, which is herein incorporated by reference in its entirety.

### BACKGROUND

### 1. Technical Field

Various embodiments of the present disclosure generally relate to a semiconductor memory and, more particularly, to a switching element, a resistive memory device including the switching element, and methods of manufacturing the switching element and the resistive memory device.

### 2. Related Art

A cross-point memory array structure has been employed in cell regions of highly integrated memory devices. More specifically, the cross-point memory array structure has been applied to memory devices such as resistive random access memory (ReRAM) devices, phase change random access memory (PCRAM) devices, magnetic random access memory (MRAM) devices, as a cell structure. The cell structure includes a pillar, which is interposed between electrodes that are disposed on different planes and that intersect with each other.

Meanwhile, in the cross-point memory array structure, an undesired sneak current between adjacent cells may be generated, leading to writing errors or reading errors. In order to reduce the write errors or the read errors, a selection element may be employed in each memory cell of memory devices. A switching element such as a transistor, a diode, a tunnel barrier device, or an ovonic threshold switch has been used as the selection element.

### SUMMARY

Various embodiments are directed to a switching element having a pillar-shaped structure, a resistive memory device employing the switching element as a selection element of a memory cell, and methods of manufacturing the switching element and the resistive memory device.

According to an embodiment, a method of manufacturing a switching element includes forming a pillar-shaped structure including a first electrode, an insulation layer, and a second electrode over a substrate, and performing a dopant injection process to form a first doping region in the insulation layer. The method further includes performing the dopant injection process to form a second doping region in the first electrode, to form a third doping region in the second electrode, or both. The first and second doping regions form a first interface therebetween, and the first and third doping regions form a second interface therebetween. The first doping region corresponds to a region in which a threshold switching operation performed.

According to an embodiment, there is provided a switching element. The switching element includes a pillar-shaped structure including a first electrode, an insulation layer and a second electrode.

The switching element further includes a first doping region disposed in the insulation material layer, and at least one of a second doping region disposed in the first electrode and a third doping region disposed in the second electrode. A first interface is disposed between the first and second doping regions, and a second interface is disposed between the first and third doping regions. The first doping region corresponds to a region in which a threshold switching operation is performed.

According to an embodiment, there is provided a method of is manufacturing a resistive memory device. The method includes forming a plurality of pillar-shaped structures over a substrate, each of the plurality of pillar-shaped structures including a lower electrode, a resistive memory layer, a middle electrode, an insulation layer, and an upper electrode that are sequentially stacked. The method further includes performing a dopant injection process to form a first doping region in the insulation material layer, and performing the dopant injection process to form a second doping region in the middle electrode, to form a third doping region in the upper electrode, or both. The first and second doping regions form an interface therebetween. The first doping region corresponds to a region in which a threshold switching operation is performed.

According to an embodiment, there is provided a resistive memory device. The resistive memory device includes a plurality of a pillar-shaped structure. Each of the plurality of pillar-shaped structure includes a lower electrode, a resistive memory layer, a middle electrode, an insulation layer, and an upper electrode that are sequentially stacked. The resistive memory device further includes a first doping region disposed in the insulation material layer, and at least one of a second doping region disposed in the first electrode and a third doping region disposed in the second electrode. A first interface is disposed between the first and second doping regions, and a second interface is disposed between the first and third doping regions. The first doping region corresponds to a region in which a threshold switching operation is performed.

### BRIEF DESCRIPTION OF THE DRAWINGS

Various embodiments of the present disclosure will become more apparent in view of the attached drawings and accompanying detailed description, in which:

FIG. 1 is a perspective view illustrating a cross-point array device according to an embodiment;

FIG. 2 is an enlarged view illustrating a portion of the cross-point array device shown in FIG. 1;

FIG. 3A is a vertical cross-sectional view illustrating a switching element according to a first embodiment;

FIG. 3B is a horizontal cross-sectional view illustrating an insulation layer of the switching element illustrated in FIG. 3A;

FIG. 4A is a vertical cross-sectional view illustrating a switching element according to a second embodiment;

FIG. 4B is a horizontal cross-sectional view illustrating an insulation layer of the switching element illustrated in FIG. 4A;

FIG. 5A is a vertical cross-sectional view illustrating a switching element according to a third embodiment;

FIG. 5B is a horizontal cross-sectional view illustrating an insulation layer of the switching element illustrated in FIG. 5A;

FIG. 6A is a vertical cross-sectional view illustrating a switching element according to a fourth embodiment;

FIG. 6B is a horizontal cross-sectional view illustrating an insulation layer of the switching element illustrated in FIG. 6A;

FIG. 7 is a flow chart illustrating a method of manufacturing a switching element according to an embodiment;

FIGS. 8A to 12A are plan-views illustrating a method of manufacturing a resistive random access memory (ReRAM) device according to an embodiment;

FIGS. 8B to 12B are cross-sectional views taken along a line I-I′ of FIGS. 8A to 12A, respectively; and

FIGS. 8C to 12C are cross-sectional views taken along a line II-II′ of FIGS. 8A to 12A, respectively.

### DETAILED DESCRIPTION

The present disclosure will be described hereinafter with reference to the accompanying drawings, in which embodiments of the present disclosure are shown. In the drawings, the size, width, and/or thickness of components may be slightly increased in order to clearly express the components of each device. The drawings are described in the observer's point overall, thus, the expression “upper” or “lower” described herein may also be interpreted as “lower” or “upper” in accordance with a change of the observer's view point. If an element is referred to be located on another element, it may be understood that the element is directly located on the other element, or an additional element may be interposed between the element and the other element. The same reference numerals refer to the same elements throughout the specification.

In addition, expression of the singular form should be understood to include the plural forms unless clearly used otherwise in the context. It will be understood that the terms “comprise” or “have” are intended to specify the presence of a feature, a number, a step, an operation, an element, a part or combinations thereof, but not used to preclude the presence or possibility of addition one or more other features, numbers, steps, operations, components, parts or combinations thereof.

In accordance with embodiments of the present disclosure, there may be provided a switching element performing a threshold switching operation. The term “threshold switching operation” described herein means an operation in which the switching element is turned on or off while an external voltage is applied to the switching element. In such a case, an absolute value of the external voltage may gradually increase or decrease. When the absolute value of the external voltage applied to the switching element increases, the switching element may be turned on, thereby causing an operation current to increase when the absolute value of the external voltage is greater than a first threshold voltage. When the absolute value of the external voltage applied to the switching element is reduced after the switching element is turned on, the switching element may be turned off, thereby causing the operation current to decrease when the absolute value of the external voltage is less than a second threshold voltage. As such, the switching element performing the threshold switching operation may have a non-memory operation characteristic.

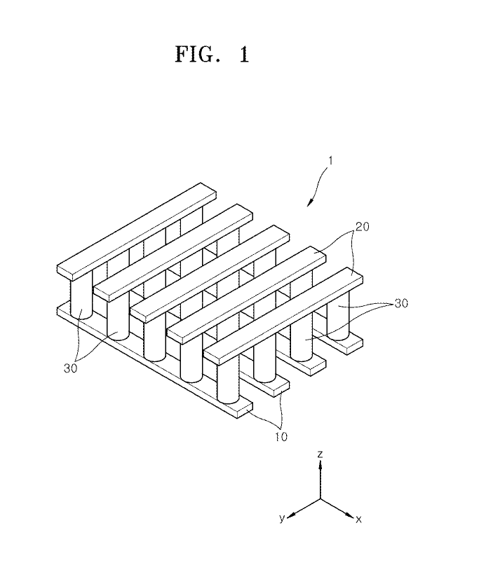

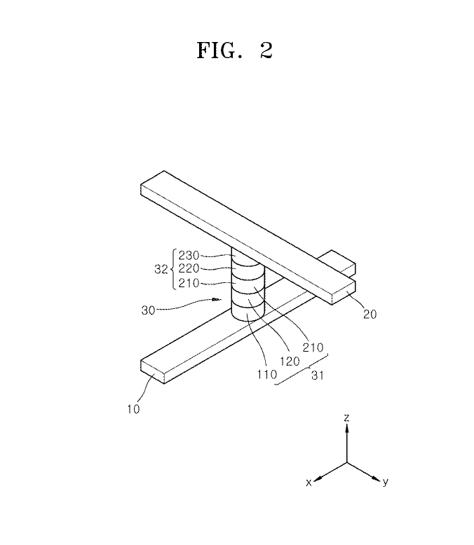

FIG. 1 is a perspective view schematically illustrating a cross-point array device 1 according to an embodiment. FIG. 2 is an enlarged view illustrating a portion of the cross-point array device 1 illustrated in FIG. 1.

Referring to FIG. 1, the cross-point array device 1 may include first conductive lines 10 extending in an x-direction, second conductive lines 20 extending in a y-direction, and pillar-shaped structures 30. The pillar-shaped structures 30 are disposed at regions where the first conductive lines 10 and the second conductive lines 20 intersect, and the pillar-shaped structures 30 extend in a z-direction. Although FIG. 1 illustrates an example in which a three-dimensional rectangular coordinate system of the x-direction, the y-direction, and the z-direction is used, any one of various coordinate systems may be used to describe the cross-point array device 1. In such a case, the x-direction and the y-direction may intersect with each other at a non-perpendicular angle, and the z-direction may be perpendicular to both of the x-direction and the y-direction. The pillar-shaped structures 30 may constitute a plurality of arrays along the x-direction and the y-direction.

Referring to FIG. 2, each of the pillar-shaped structures 30 may include a lower electrode 110, a resistive memory layer 120, a middle electrode 210, an insulation layer 220, and an upper electrode 230. The lower electrode 110, the resistive memory layer 120, and the middle electrode 210 may constitute a variable resistive element 31. The middle electrode 210, the insulation layer 220, and the upper electrode 230 may constitute a selection element 32. The variable resistive element 31 may share the middle electrode 210 with the selection element 32. Accordingly, the cross-point array device 1 illustrated in FIGS. 1 and 2 may function as an ReRAM device including memory cells, each of which includes the variable resistive element 31 and the selection element 32.

The ReRAM device may be defined as a memory device that identifies data stored in a selected one of the pillar-shaped structures 30 disposed between the first conductive lines 10 and the second conductive lines 20, on the basis of an amount of a current flowing through the selected pillar-shaped structure 30. In some embodiments, the cross-point array device 1 may function as a PCRAM device or an MRAM device. The variable resistive element 31 may have a memory characteristic relating to an electrical resistance value of the resistive memory layer 120. In contrast, the selection element 32 may perform a threshold switching operation in response to an external voltage applied thereto, rather than having the memory characteristic.

In the variable resistive element 31, each of the lower electrode 110 and the middle electrode 210 may include a metal material, a conductive nitride material, a conductive oxide material, or the like. In some embodiments, each of the lower electrode 110 and the middle electrode 210 may include gold (Au), aluminum (Al), platinum (Pt), copper (Cu), silver (Ag), ruthenium (Ru), titanium (Ti), iridium (Ir), tungsten (W), titanium nitride (TiN), tantalum nitride (TaN), ruthenium oxide (RuO₂), or the like.

In the variable resistive element 31, the resistive memory layer 120 may include a material having a high resistive state or a low resistive state according to an externally applied voltage. In some embodiments, the resistive memory layer 120 may include a metal oxide material such as a titanium oxide material, an aluminum oxide material, a nickel oxide material, a copper oxide material, a zirconium oxide material, a manganese oxide material, a hafnium oxide material, a tungsten oxide material, a tantalum oxide material, a niobium oxide material, or an iron oxide material.

In another embodiment, the resistive memory layer 120 may include a perovskite material such as a praseodymium calcium manganese oxide (Pr_{0.7}Ca_{0.3}MnO₃) material, a La₁₋ₓCaₓMnO₃ (LCMO) material, a Ba_{0.5}Sr_{0.5}Co_{0.8}Fe_{0.2}O_{3-δ} (BSCFO) material, a YBa₂Cu₃O₇₋ₓ (YBCO) material, a (Ba, Sr)Tio₃(Cr, Nb-doped) material, a SrZrO₃(Cr, V-doped) material, a (La, Sr)MnO₃ material, a Sr₁₋ₓLaₓTiO₃ material, a La₁₋ₓSrₓFeO₃ material, a La₁₋ₓSrₓCoO₃ material, a SrFeO_{2.7} material, a LaCoO₃ material, a RuSr₂GdCu₂O₃ material, or a YBa₂Cu₃O₇ material.

In yet another embodiment, the resistive memory material layer 120 may include a selenide material such as a GeₓSe₁₋ₓ(Ag, Cu, Te-doped), or a metal sulfide material, for example, an Ag₂S material, a Cu₂S material, a CdS material, or a ZnS material.

The selection element 32 may be electrically connected to the variable resistive element 31 in series. The selection element 32 may suppress an occurrence of a sneak current between the adjacent pillar-shaped structures 30 while the cross-point array device 1 operates. In an embodiment, an amount of the sneak current may be proportional to an amount of an off-current generated in the selection element 32 when the selection element 32 is turned off.

In the selection element 32, the insulation layer 220 may include a silicon oxide material, a silicon nitride material, a metal oxide material, a metal nitride material, or a combination thereof. In some embodiments, the insulation layer 220 may include an aluminum oxide material, a zirconium oxide material, a hafnium oxide material, a tungsten oxide material, a titanium oxide material, a nickel oxide material, a copper oxide material, a manganese oxide material, a tantalum oxide material, a niobium oxide material, or an iron oxide material. The insulation layer 220 may include a compound material having a composition that does not satisfy a stoichiometric ratio. The insulation layer 220 may have an amorphous structure.

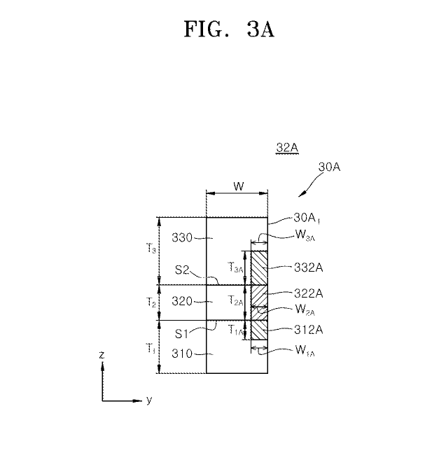

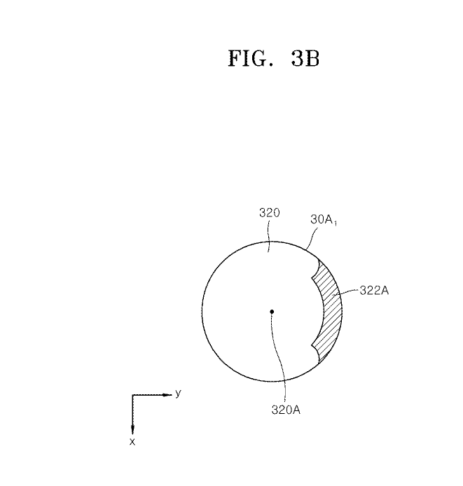

The selection element 32 may have one of structures that will be described below in more detail with reference to FIGS. 3A to 6B. For example, the selection element 32 may include a first doping region disposed in the insulation layer 220. The first doping region may be formed by doping at least a portion of the insulation layer 220 with dopants. A size of the first doping region may be controlled by a distribution area of the dopants. Specifically, the dopants may be distributed by implanting dopants into a portion of the insulation layer 220 and diffusing the implanted dopants to form the first doping region.

Meanwhile, the first doping region may determine a threshold switching operation region of the selection element 32. In an embodiment, according to a level of an externally applied voltage, the dopants in the first doping region may generate trap sites that capture conductive carriers or conduct the captured conductive carriers in the insulation layer 220. Accordingly, the threshold switching operation may be performed in the first doping region depending on the level of the externally applied voltage. In an embodiment, a size of the first doping region may be smaller than that of the insulation layer 220. For example, a volume of the first doping region is smaller than a volume of the insulation layer 220. In an embodiment of the present disclosure, since the threshold switching operation of the selection element 32 is performed through the threshold switching operation region corresponding to the first doping region which has the size smaller than that of the insulation layer 220, an off-current of the selection element 32corresponding to a sneak current may be effectively suppressed.

Meanwhile, a second doping region may be formed in the middle electrode 210 and a third doping region may be formed in the upper electrode 230. At least one of the second doping region and the third doping region is formed to be adjacent to the insulation layer 220. The second doping region and the third doping region may be doped with the same type of dopants as the dopants in the first doping region.

The dopants in the second doping region may change an energy barrier height formed at an interface between the middle electrode 210 and the insulation layer 220. The dopants in the third doping region may change an energy barrier height formed at an interface between the upper electrode 230 and the insulation layer 220. In an embodiment, because the dopants in the second doping region or the third doping region increase the energy barrier height at the corresponding interface, the off-current of the selection element 32 may be further suppressed.

FIG. 3A is a vertical cross-sectional view illustrating a switching element 32A suitable for use as the switching element 32 of FIG. 2 according to a first embodiment. FIG. 3B is a horizontal cross-sectional view illustrating an insulation layer 320 of the switching element 32A of FIG. 3A. The switching element 32A in FIGS. 3A and 3B may be obtained by cutting the pillar-shaped structure 30 of FIG. 2 in a direction perpendicular to an x-y plane, and in a direction parallel to the x-y plane, respectively.

Referring to FIG. 3A, the switching element 32A may include a pillar-shaped structure 30A. The pillar-shaped structure 30A includes a first electrode 310, the insulation layer 320, and a second electrode 330. The switching element 32A may include first to third doping regions 312A, 322A, and 332A that are disposed in the first electrode 310, the insulation layer 320, and the second electrode 330, respectively.

In an embodiment, when the pillar-shaped structure 30A has a predetermined width W in a first direction (e.g., the y-direction), the first to third doping regions 312A, 322A, and 332A may have widths W_{1A}, W_{2A}, and W_{3A}, respectively, that are smaller than a width W of the pillar-shaped structure 30A in a width direction (e.g., the y-direction). In an embodiment, the widths W_{1A}, W_{2A}, and W_{3A} of the first to third doping regions 312A, 322A, and 332A may be substantially equal to each other. In other embodiments, at least one of the widths W_{1A}, W_{2A}, and W_{3A} of the first to third doping regions 312A, 322A, and 332A may be smaller or greater than the widths of the remaining doping regions.

In addition, in other embodiments, the width W_{1A} of the first doping region 312A may vary along a second direction (e.g., the z-direction), while satisfying a condition that the width W_{1A} of the first doping region 312A is smaller than the width W of the pillar-shaped structure 30A. Likewise, the widths W_{2A} and W_{3A} of the second doping region 322A and the third doping region 332A may vary along the z-axis direction, respectively, while satisfying a condition that the widths W_{2A} and W_{3A} of the second doping region 322A and the third doping region 332A are smaller than the width W of the pillar-shaped structure 30A.

When the first electrode 310 has a predetermined thickness T₁ in the z-direction, the first doping region 312A may have a thickness T_{1A} that is equal to or less than the thickness T₁ of the first electrode 310. When the insulation layer 320 has a predetermined thickness T₂, the second doping region 322A may have a thickness T_{2A} that is substantially equal to the thickness T₂ of the insulation layer 320. When the second electrode 330 has a predetermined thickness T₃, the third doping region 332A may have a thickness T_{3A} that is equal to or less than the thickness T₃ of the second electrode 330.

The first to third doping regions 312A, 322A, and 332A may include dopants in the first electrode 310, the insulation layer 320, and the second electrode 330, respectively. According to a level of an externally applied voltage, the dopants may generate trap sites that capture conductive carriers in the second doping region 322A or conduct the captured conductive carriers. When the externally applied voltage is lower than a predetermined threshold voltage, the trap sites may capture the conductive carriers such as electrons or holes. On the other hand, when the externally applied voltage is equal to or greater than the threshold voltage, the trap sites may conduct the captured conductive carriers. The second doping region 322A may determine a threshold switching operation region in which the threshold switching operation of the switching element 32A is performed.

Meanwhile, the first doping region 312A may form an interface S1 with the insulation layer 320. In the embodiment shown in FIG. 3A, the first doping region 312A in the first electrode 310 may form such an interface S1 with the second doping region 322A in the insulation layer 320 since the second doping region 322A may have the thickness T_{2A} that is substantially equal to the thickness T₂ of the insulation layer 320. In addition, the third doping region 332A may form an interface S2 with the insulation layer 320. In the embodiment shown in FIG. 3A, the third doping region 332A in the second electrode 330 may form such an interface S2 with the second doping region 322A in the insulation layer 320 since the second doping region 322A may have the thickness T_{2A} that is substantially equal to the thickness T₂ of the insulation layer 320.

The dopants in the first doping region 312A and the third doping region 332A may change an electrical characteristic, such as a Fermi energy level Ef, of the first electrode 310 and the second electrode 330, respectively. As a result, the dopants in the first doping region 312A may change an energy barrier height formed at the interface S1 between the first electrode 310 and the insulation layer 320. Likewise, the dopants in the third doping region 332A may change an energy barrier height formed at the interface S2 between the second electrode 330 and the insulation layer 320. Accordingly, it is possible to change the energy barrier height formed at the interface S1 between the first electrode 310 and the insulation layer 320, and to change the energy barrier height formed at the interface S2 between the second electrode 330 and the insulation layer 320, by adjusting amounts of the dopants in the first doping region 312A and the third doping region 332A, respectively.

In an embodiment, the dopants may be selected from materials satisfying both conditions that the dopants can generate trap sites of conductive carriers in the insulation layer 320, and that the dopants can increase the energy barrier height between the first electrode 310 and the insulation layer 320 and the energy barrier height between the second electrode 330 and the insulation layer 320. Using the selected dopants, when an applied voltage has a level that is equal to or less than a predetermined threshold voltage, conductive carriers moving beyond the energy barrier may be captured by the trap sites in the insulation layer 320. Further, the conductive carriers moving beyond the energy barrier may be suppressed by the increased energy barrier height between the first electrode 310 and the insulation layer 320 or between the second electrode 330 and the insulation layer 320. As a result, an off-current may be effectively suppressed. When the applied voltage has a level that is equal to or greater than the predetermined threshold voltage, the captured conductive carriers flow through the insulation layer 320. Thus, a threshold switching operation of the switching element 32A to turn on or off the switching element 32A is performed according to the level of the applied voltage.

Referring to FIG. 3A, the first to third doping regions 312A, 322A, and 332A may be disposed in a sidewall portion of the pillar-shaped structure 30A. Referring to FIG. 3B, the second doping region 322A may be formed to extend from an outer surface 30A₁ of the insulation layer 320 toward a central axis 320A of the insulation layer 320 and to have a predetermined thickness in a radial direction of the pillar-shaped structure 30A. In an embodiment, cross-sectional shapes (not shown) of the first and third doping regions 312A and 332A may be substantially the same as a cross-sectional shape of the second doping region 322A of FIG. 3B.

In other embodiments, the first electrode 310 is not doped, and thus the first doping region 312A among the first to third doping regions 312A to 332A of the pillar-shaped structure 30A may be omitted. Alternatively, in other embodiments, the second electrode 330 is not doped, and thus the third doping region 332A among the first to third doping regions 312A to 332A of the pillar-shaped structure 30A may be omitted.

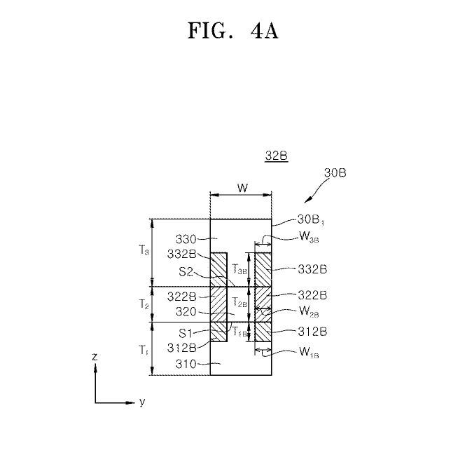

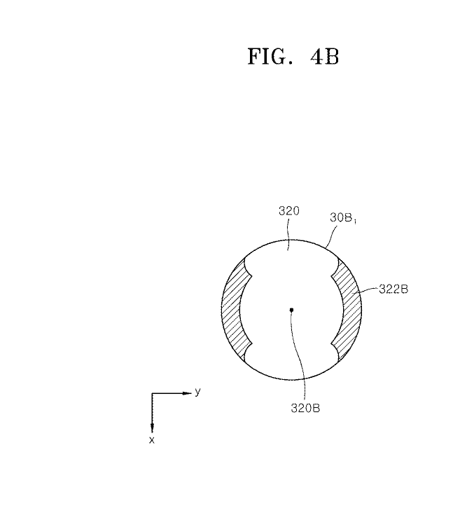

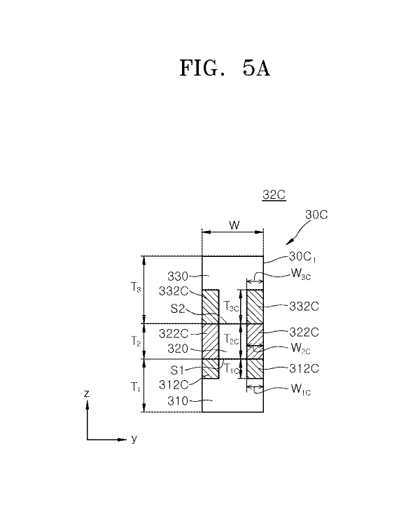

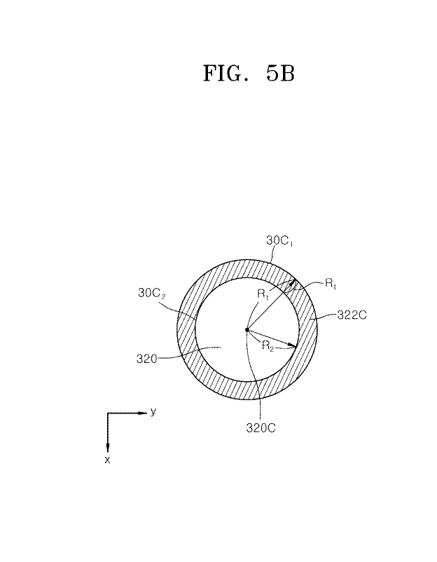

FIG. 4A is a vertical cross-sectional view illustrating a switching element 32B suitable for use as the switching element 32 of FIG. 2 according to a second embodiment. FIG. 4B is a horizontal cross-sectional view illustrating an insulation layer 320 of the switching element illustrated in FIG. 4A. The switching element 32B in FIGS. 4A and 4B may be obtained by cutting the pillar-shaped structure 30 of FIG. 2 along a direction that is perpendicular to the x-y plane, and a direction that is parallel to the x-y plane, respectively.

Referring to FIG. 4A, the switching element 32B may include a pillar-shaped structure 30B. The pillar-shaped structure 30B includes a first electrode 310, the insulation layer 320, and a second electrode 330. First to third doping regions 312B, 322B, and 332B may be disposed in two sidewall portions of the pillar-shaped structure 30B. Widths W_{1B}, W_{2B}, and W_{3B} and thicknesses T_{1B}, T_{2B}, and T_{3B} of the first to third doping regions 312B, 322B and 332B may have substantially the same dimensions and configuration as the widths W_{1A}, W_{2A}, and W_{3A} and the thicknesses T_{1A}, T_{1B}, and T_{3A} of the first to third doping regions 312A, 322A, and 332A of FIGS. 3A and 3B, except a cross-sectional shape as will be described below with reference to FIG. 4B.

Referring to FIG. 4B, the second doping regions 322B may be symmetrically disposed with respect to a central axis 320B of the pillar-shaped structure 30B. Each of the second doping regions 322B may be formed to extend from an outer surface 30B₁ of the pillar-shaped structure 30B toward the central axis 320B of the pillar-shaped structure 30B, and to have a predetermined thickness in a radial direction of the pillar-shaped structure 30B. Although FIGS. 4A and 4B show that the two second doping regions 322B are symmetrically disposed with respect to the central axis 320B, but embodiments of the present disclosure are not limited thereto. For example, three or more second doping regions 322B may be spaced apart from each other such that the second doping regions 322B are symmetrically disposed with respect to the central axis 320B of the pillar-shaped structure 30B. In an embodiment, cross-sectional shapes (not shown) of the first doping region 312B and the third doping region 332B may be substantially the same as the cross-sectional shape of the second doping region 322B of FIG. 4B.

In other embodiments, the first electrode 310 is not doped, and thus the first doping regions 312B among the first to third doping regions 312B to 332B may be omitted. In other embodiments, the second electrode 330 is not doped, and thus the third doping regions 332B among the first to third doping regions 312B to 332B may be omitted.

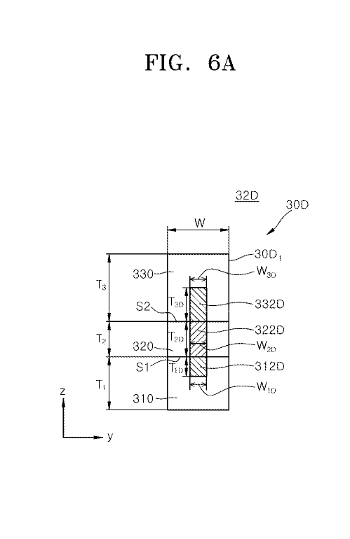

FIG. 5A is a vertical cross-sectional view illustrating a switching element 32C suitable for use as the switching element 32 of FIG. 2 according to a third embodiment. FIG. 5B is a horizontal cross-sectional view illustrating an insulation layer 320 of the switching element 32C illustrated in FIG. 5A. The switching element 32C in FIGS. 5A and 5B may be obtained by cutting the pillar-shaped structure 30 of FIG. 2 along a direction that is perpendicular to the x-y plane, and a direction that is parallel to the x-y plane, respectively.

Referring to FIG. 5A, the switching element 32C may include a pillar-shaped structure 30C. The pillar-shaped structure 30C has a first electrode 310, the insulation layer 320, and a second electrode 330. First to third doping regions 312C, 322C and 332C may be disposed in a sidewall portion of the pillar-shaped structure 30C. Widths W_{1C}, W_{2C}, and W_{3C} and thicknesses T_{1C}, T_{2C}, and T_{3C} of the first to third doping regions 312C, 322C, and 332C may have substantially the same dimensions and configuration as the widths W_{1B}, W_{2B}, and W_{3B} and the thicknesses T_{1B}, T_{2B}, and T_{3B} of the first to third doping regions 312B, 322B, and 332B of FIGS. 4A and 4B, except a cross-sectional shape as will be described below with reference to FIG. 5B.

Referring to FIG. 5B, the second doping region 322C may be disposed along an outer surface of the pillar-shaped structure 30C. The second doping region 322C may be disposed in an annular shape (or a ring shape) extending from an outer surface 30C₁ of the pillar-shaped structure 30C toward a central axis 320C and having a predetermined thickness Rₜ in a radial direction of the pillar-shaped structure 30C. More specifically, when the pillar-shaped structure 30C has a first radius R₁ from the central axis 320C to the outer surface 30C₁ and a second radius R₂ from the central axis 320C to an inner surface 30C₂ of the second doping region 322C, the second doping region 322C may have the thickness Rₜ corresponding to a difference between the first radius R₁ and the second radius R₂. In an embodiment, cross-sectional shapes (not shown) of the first and third doping region 312C and 332C may be substantially the same as the cross-sectional shape of the second doping region 322C of FIG. 5B.

In other embodiments, the first electrode 310 is not doped, and thus the first doping region 312C among the first to third doping regions 312C to 332C may be omitted. In other embodiments, the second electrode 330 is not doped, and thus the third doping region 332C among the first to third doping regions 312C to 332C may be omitted.

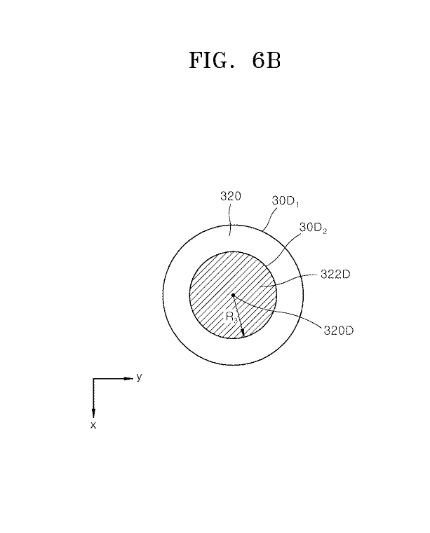

FIG. 6A is a vertical cross-sectional view illustrating a switching element 32D suitable for use as the switching element 32 of FIG. 2 according to a fourth embodiment. FIG. 6B is a horizontal cross-sectional view illustrating an insulation layer 320 of the switching element 32D illustrated in FIG. 6A. The switching element 32D in FIGS. 6A and 6B may be obtained by cutting the pillar-shaped structure 30 of FIG. 2along a direction that is perpendicular to the x-y plane, and a direction that is parallel to the x-y plane, respectively.

Referring to FIG. 6A, the switching element 32D may include a pillar-shaped structure 30D. The pillar-shaped structure 30D includes a first electrode 310, the insulation layer 320, and a second electrode 330. First to third doping regions 312D, 322D, and 332D may be disposed in an inner portion spaced apart from an outer surface 30D₁ of the pillar-shaped structure 30D. Widths W_{1D}, W_{2D}, and W_{3D} and thicknesses T_{1D}, T_{2D}, and T_{3D} of the first to third doping regions 312D, 322D, and 332D may have substantially the same dimensions and configuration as the widths W_{1B}, W_{2B}, and W_{3B} and thicknesses T_{1B}, T_{2B}, and T_{3B} of the first to third doping regions 312B, 322B, and 332B of FIGS. 4A and 4B, except a cross-sectional shape as will be described below with reference to FIG. 6B.

Referring to FIG. 6B, the second doping region 322D may be disposed in the inner portion of the pillar-shaped structure 30D, which is spaced apart from the outer surface 30D₁ of the pillar-shaped structure 30D. In the embodiment shown in FIG. 6B, the second doping region 322D may be disposed in a portion having a predetermined radius R₃ from a central axis 320D of the pillar-shaped structure 30D to an inner surface 30D₂. In another embodiment, the second doping region 322D may have a different shape, and may not be symmetrical with respect to the central axis 320D. In an embodiment, cross-sectional shapes (not shown) of the first and third doping regions 312D and 332D may be substantially the same as the cross-sectional shape of the second doping region 322D of FIG. 6B.

In other embodiments, the first electrode 310 is not doped, and thus the first doping region 312D among the first to third doping regions 312D to 332D may be omitted. In other embodiments, the second electrode 330 is not doped, and thus the third doping region 332D among the first to third doping regions 312D to 332D may be omitted.

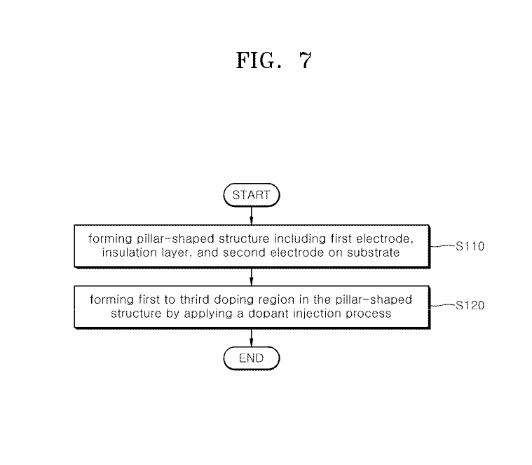

FIG. 7 is a flowchart illustrating a process of manufacturing a switching element according to an embodiment. The process may be applied to manufacture the selection element 32 of the cross-point array device 1 described with reference to FIGS. 1 and 2.

Referring to FIG. 7, at step S110, a plurality of pillar-shaped structures may be formed on a substrate. Each of the plurality of pillar-shaped structures may have a first electrode, an insulation layer, and a second electrode. In an embodiment, the pillar-shaped structures may be formed as follows. A first electrode layer, an insulation material layer, and a second electrode layer may be sequentially formed on the substrate. The first electrode layer, the insulation material layer, and the second electrode layer may be patterned to form the pillar-shaped structures, which are arranged in a plurality of rows and columns. After patterning, each of the pillar-shaped structures may include a first electrode, an insulation layer, and a second electrode. In some embodiments, the insulation layer may include at least one selected from a silicon oxide material, a silicon nitride material, a metal oxide material, and a metal nitride material.

At step S120, first to third doping regions may be formed by injecting dopants into the pillar-shaped structures. At this time, the first doping region, the second doping region, and the third doping region may be formed in the first electrode, in the insulation layer, and in the second electrode, respectively. The first and third doping regions may form first and second interfaces with the insulation layer, respectively.

The dopants may include at least one selected from the group consisting of aluminum (Al), lanthanum (La), niobium (Nb), vanadium (V), tantalum (Ta), tungsten (W), chrome (Cr), molybdenum (Mo), titanium (Ti), copper (Cu), zirconium (Zr), and hafnium (Hf). The dopants may generate trap sites that capture conductive carriers in the second doping region and conduct the captured conductive carriers. Accordingly, the second doping region may function as a threshold switching operation region of the switching element.

Through the dopant injection, it is possible to change an energy barrier height formed at the first interface between the first electrode and the insulation layer and to change an energy barrier height formed at the second interface between the second electrode and the insulation layer. Accordingly, the dopants may be selected from materials satisfying both conditions that the dopants can generate trap sites of the conductive carriers in the insulation layer, and can increase the energy barrier height between the first electrode and the insulation layer and the energy barrier height between the second electrode and the insulation layer.

The dopant injection may be performed on a sidewall portion of the pillar-shaped structure using a tilted ion implantation (I²) process. In some embodiments, through the tilted I² process, the first to third doping regions 312A, 312B, 322A, 322B, 332A, and 332B may be formed in sidewall portions of the pillar-shaped structures 30A and 30B, as shown in FIGS. 3A, 3B, 4A, and 4B.

In another embodiment, the tilted I² process may be performed such that a distribution of the injected dopant ions forms a ring extending from the outer surface 30C₁ of the pillar-shaped structure 30C toward the central axis 320C and having the predetermined thickness Rₜ, as shown in FIGS. 5A and 5B. In yet another embodiment, the tilted I² process may be performed such that the injected dopant ions are distributed in an inner portion of the pillar-shaped structure 30D, which is spaced apart from the outer surface 30D₁ of the pillar-shaped structure 30D, as shown in FIGS. 6A and 6B.

In other embodiments, when performing the dopant injection process, the second electrode may be selectively blocked not to form the third doping region. In other embodiments, when performing the tilted I² process, process conditions such as an ion implantation angle may be changed not to form the first doping region in the first electrode.

According to an embodiment of the present disclosure, the threshold switching operation region of the switching element may be formed by injecting dopants into at least two portions of the first electrode, the insulation layer, and the second electrode of the pillar-shaped structure. In a conventional process, the first electrode layer, the insulation material layer, and the second electrode layer are patterned to form a plurality of pillar-shaped structures, each of which has a size sufficiently small to suppress an off-current. The above-described process according to the embodiment of the present disclosure may substitute for the conventional process, in order to reduce a size of a plurality of threshold switching operation regions respectively located in the pillar-shaped structures and to reduce an off-current in each of the pillar-shaped structures. Accordingly, the burden on manufacturing process of the switching element according to the embodiment of the present disclosure can be reduced. Also, the injected dopants can reduce the off-current by increasing an energy barrier height at an interface between the first electrode and the insulation layer, and at an interface between the second electrode and the insulation layer. According to an embodiment of the present disclosure, the off-current of the switching element can be effectively reduced and an operation reliability of the switching element can be improved.

Hereinafter, a method of manufacturing an ReRAM device including the switching element as a selection element will be described in detail.

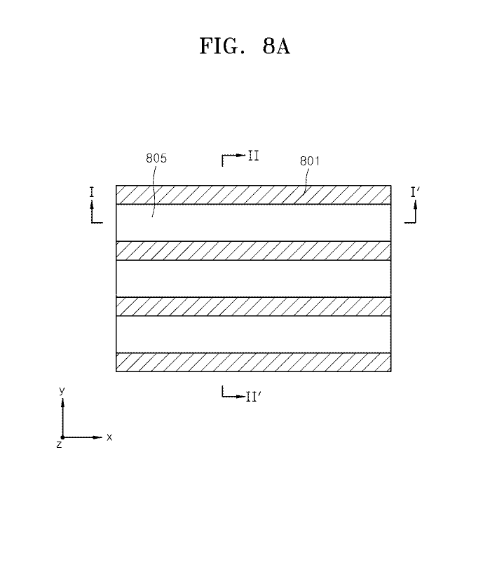

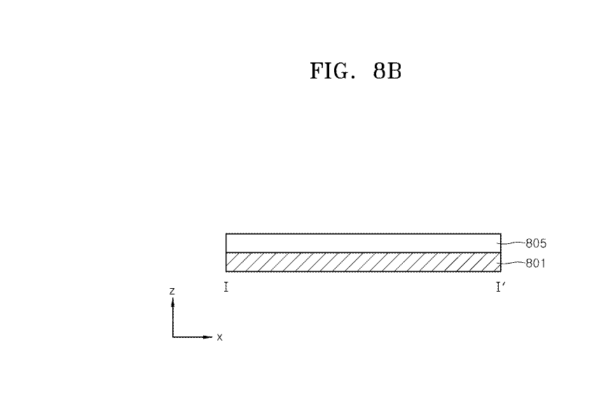

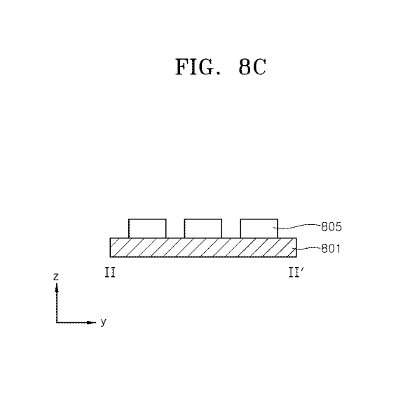

FIGS. 8A, 9A, 10A, 11A, and 12A are plan-views illustrating a method of manufacturing an ReRAM device according to an embodiment. FIGS. 8B, 9B, 10B, 11B, and 12B are cross-sectional views taken along a line I-I′ of FIGS. 8A, 9A, 10A, 11A, and 12A, respectively. FIGS. 8C, 9C, 10C, 11C, and 12C are cross-sectional views taken along a line II-II' of FIGS. 8A, 9A, 10A, 11A, and 12A, respectively.

Referring to FIGS. 8A, 8B, and 8C, lower conductive lines 805 may be formed on a substrate 801, and each of the lower conductive lines 805 extends in a first direction (e.g., an x-direction). In an embodiment, a process for forming the lower conductive lines 805 may include forming a conductive layer on the substrate 801 using a deposition process, and patterning the conductive layer using a lithography process and an etching process to form the lower conductive lines 805 in line shapes.

In some embodiments, the substrate 801 may be a silicon substrate or a gallium arsenide substrate. However, embodiments of the present disclosure are not limited thereto. In some embodiments, the substrate 801 may be a ceramic substrate, a polymer substrate, or a metallic substrate to which semiconductor processes are applicable. The substrate 801 may include an integrated circuit therein. Each of the lower conductive lines 805 may include a known metal material, a conductive metal nitride material, a conductive metal oxide material, or the like.

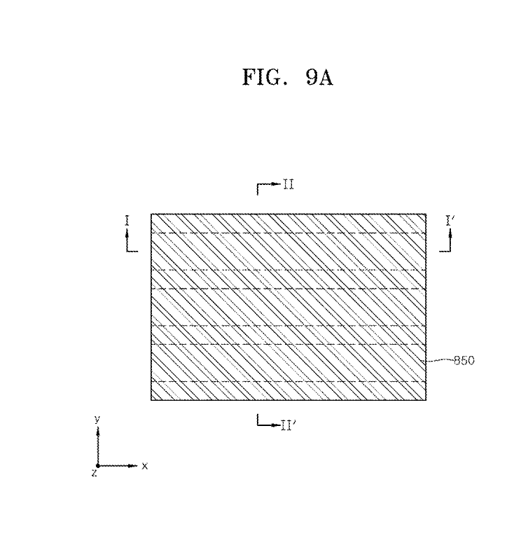

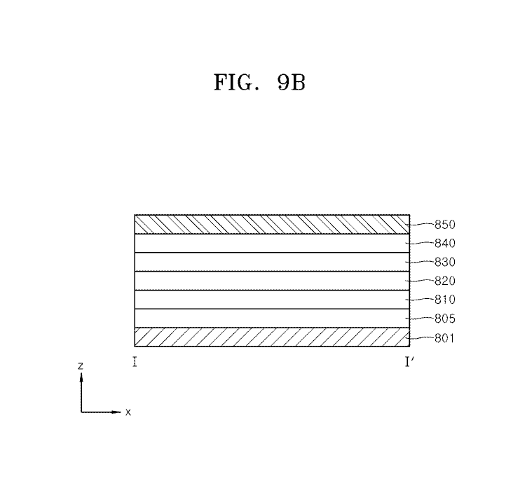

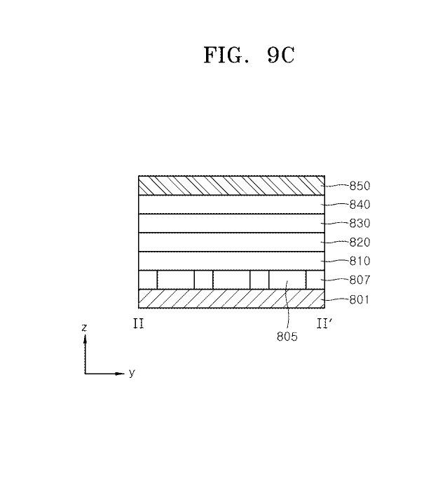

Referring to FIGS. 9A, 9B, and 9C, a lower insulation material layer 807 may be formed to fill spaces between the lower conductive lines 805. In an embodiment, an insulation material is deposited over the substrate 801 and the lower conductive lines 805, and the deposited material is planarized until top surfaces of the lower conductive lines 805 are exposed. Subsequently, a lower electrode layer 810, a resistive memory material layer 820, a middle electrode layer 830, an insulation material layer 840, and an upper electrode layer 850 may be sequentially formed over the lower conductive lines 805 and the lower insulation material layer 807.

Each of the lower electrode layer 810, the middle electrode layer 830, and the upper electrode layer 850 may include a metal material, a conductive metal nitride material, or a conductive metal oxide material. In an embodiment, each of the lower electrode layer 810, the middle electrode layer 830, and the upper electrode layer 850 may include gold (Au), platinum (Pt), copper (Cu), aluminum (Al), silver (Ag), ruthenium (Ru), titanium (Ti), iridium (Ir), tungsten (W), titanium nitride (TiN), tantalum nitride (TaN), or ruthenium oxide (RuO₂). Each of the lower electrode layer 810, the middle electrode layer 830, and the upper electrode layer 850 may be formed using a sputtering process, an atomic layer deposition (ALD) process, an evaporation process, a chemical vapor deposition (CVD) process, or an electron beam deposition process.

In an embodiment, the resistive memory material layer 820 may include a metal oxide material such as a titanium oxide material, an aluminum oxide material, a nickel oxide material, a copper oxide material, a zirconium oxide material, a manganese oxide material, a hafnium oxide material, a tungsten oxide material, a tantalum oxide material, a niobium oxide material, or an iron oxide material. In other embodiments, the resistive memory material layer 820 may include a perovskite material such as a praseodymium calcium manganese oxide (Pr_{0.7}Ca_{0.3}MnO₃) material, a La₁₋ₓCaₓMnO₃ (LCMO) material, a Ba_{0.5}Sr_{0.5}Co_{0.8}Fe_{0.2}O_{3-δ} (BSCFO) material, a YBa₂Cu₃O₇₋ₓ (YBCO) material, a (Ba, Sr)Tio₃(Cr, Nb-doped) material, a SrZrO₃(Cr, V-doped) material, a (La, Sr)MnO₃ material, a Sr₁₋ₓLaₓTiO₃ material, a La₁₋ₓSrₓFeO₃ material, a La₁₋ₓSrₓCoO₃ material, a SrFeO_{2.7} material, a LaCoO₃ material, a RuSr₂GdCu₂O₃ material, or a YBa₂Cu₃O₇ material. In yet other embodiments, the resistive memory material layer 820 may include a selenide material such as a GeₓSe₁₋ₓ(Ag, Cu, Te-doped). In still other embodiments, the resistive memory material layer 820 may include a metal sulfide material, for example, an Ag₂S material, a Cu₂S material, a CdS material, or a ZnS material.

The resistive memory material layer 820 may be formed using a sputtering process, an atomic layer deposition (ALD) process, an evaporation process, a chemical vapor deposition (CVD) process, or an electron beam deposition process.

The insulation material layer 840 may include one of a silicon oxide material, a silicon nitride material, a metal oxide material, a metal nitride material, or a combination thereof. For example, the insulation material layer 840 may include an aluminum oxide material, a zirconium oxide material, a hafnium oxide material, a tungsten oxide material, a titanium oxide material, a nickel oxide material, a copper oxide material, a manganese oxide material, a tantalum oxide material, a niobium oxide material, or an iron oxide material.

The insulation material layer 840 may be formed using a sputtering process, an atomic layer deposition (ALD) process, an evaporation process, a chemical vapor deposition (CVD) process, or an electron beam deposition process. The above-listed compound materials for the insulation material layer 840 may have a composition that does not satisfy a stoichiometric ratio. The insulation material layer 840 may have an amorphous structure.

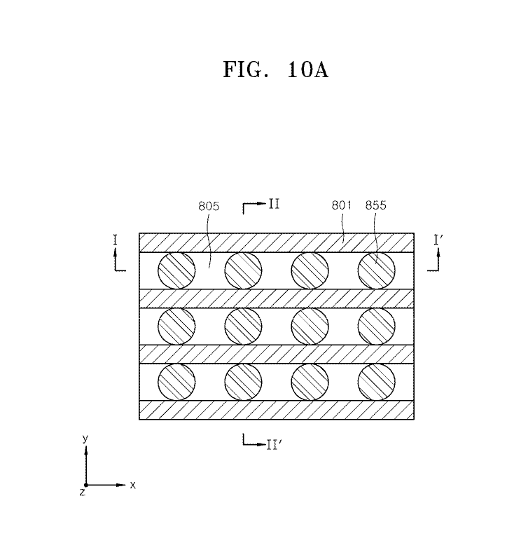

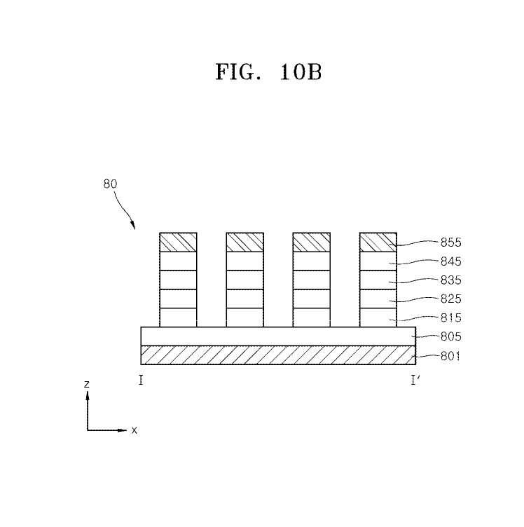

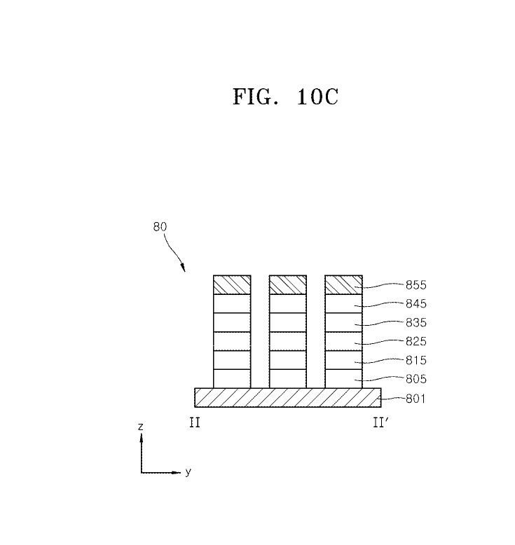

Referring to FIGS. 10A, 10B, and 10C, the upper electrode layer 850, the insulation material layer 840, the middle electrode layer 830, the resistive memory material layer 820, and the lower electrode layer 810 may be patterned to form an array of pillar-shaped structures 80 on the lower conductive lines 805. In an embodiment, the upper electrode layer 850, the insulation material layer 840, the middle electrode layer 830, the resistive memory material layer 820, and the lower electrode layer 810 are etched substantially in a vertical direction (e.g., a z-direction). Each of the pillar-shaped structures 80 may include a lower electrode 815, a resistive memory layer 825, a middle electrode 835, an insulation layer 845, and an upper electrode 855.

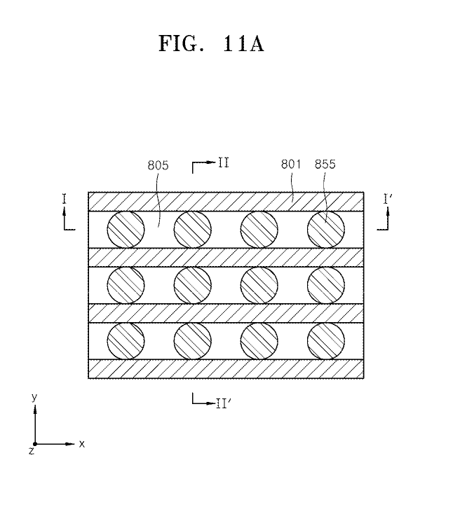

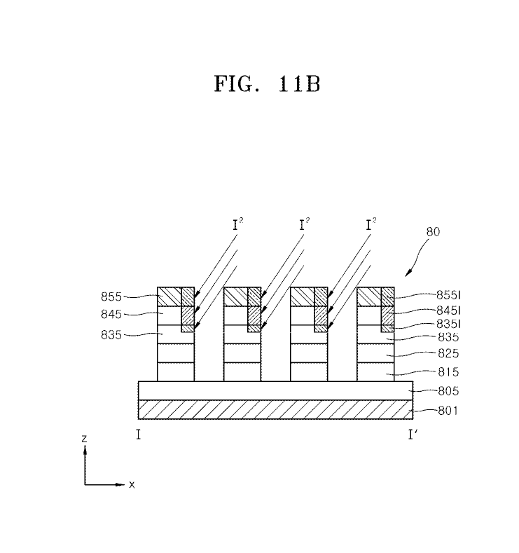

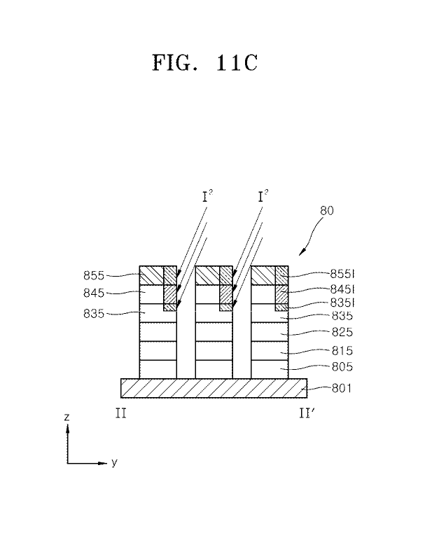

Referring to FIGS. 11A, 11B and 11C, a dopant injection process may be applied to each of the pillar-shaped structures 80 to form a first doping region 835I in the middle electrode 835, a second doping region 845I in the insulation layer 845, and a third doping region 855I in the upper electrode 855, respectively. In an embodiment, the dopant injection process may be performed using an I² process. Each of the first and third doping regions 835I and 855I may form a corresponding interface with the insulation layer 845.

The dopants may include at least one selected from the group consisting of aluminum (Al), lanthanum (La), niobium (Nb), vanadium (V), tantalum (Ta), tungsten (W), chrome (Cr), molybdenum (Mo), titanium (Ti), copper (Cu), zirconium (Zr), and hafnium (Hf). The dopants may generate trap sites that capture conductive carriers and conduct the captured conductive carriers in the second doping region 845I. Accordingly, the second doping region 845I may function as a threshold switching operation region of the switching element.

Through the dopant injection process, an energy barrier height formed at an interface between the middle electrode 835 and the insulation layer 845 can be changed by the dopants injected into the first doping region 835I in the middle electrode 835. Also, an energy barrier height formed at an interface between the upper electrode 855 and the insulation layer 845 can be changed by the dopants injected into the third doping region 855I in the upper electrode 855. Accordingly, the dopants may be selected from materials satisfying both conditions that the dopants can generate trap sites of the conductive carriers in the insulation layer 845, and can increase the energy barrier height at the interface between the middle electrode 835 and the insulation material layer 845, and the energy barrier height at the interface between the upper electrode 855 and the insulation layer 845.

In some embodiments, the dopant injection process may be performed using a tilted I² process. The tilted I² process may be performed to inject dopants into a sidewall portion of the pillar-shaped structure 80. In some embodiments, using the tilted I² process, as shown in FIGS. 3A, 3B, 4A, and 4B, the first to third doping regions 312A, 312B, 322A, 322B, 332A, and 332B may be formed in one or more sidewall portions of the pillar-shaped structures 30A and 30B. In another embodiment, the tilted I² process may be performed such that a distribution of the implanted dopants forms a ring extending from an outer surface 30C₁ toward a central axis 320C and having a predetermined thickness Rₜ in a radial direction of the pillar-shaped structure 30C, as shown in FIGS. 5A and 5B. In yet another embodiment, the tilted I² process may be performed such that the implanted dopants are distributed in an inner portion of the pillar-shaped structures 30D, which is spaced apart from the outer surface 30D₁ of the pillar-shaped structure 30D, as shown in FIGS. 6A and 6B. In the embodiment shown in FIGS. 6A and 6B, because the dopants are distributed in the inner portion of the pillar-shaped structures 30D and the inner portion is substantially free from damages due to the patterning process to form the pillar-shaped structures 30D, the threshold switching operation may be reliably performed by the switching element 32D.

Meanwhile, when performing the tilted I² process, the dopants may not be implanted into the resistive memory layer 825 by controlling at least one of a tilted angle, an ion dose, and an implantation energy of the tilted I² process. Accordingly, it is possible to prevent the resistive memory layer 825 from being damaged by the tilted I² process or properties of the resistive memory layer 825 from being changed by the implanted dopants.

In some embodiments, when performing the tilted I² process, the tilted I² process may be performed after forming a protection layer that selectively shields the upper electrode 855, and thus, the third doping region 855I may not be formed in the upper electrode 855. Accordingly, only the first and second doping regions 835I and 845I may be formed in the middle electrode 835 and in the insulation layer 845, respectively. The protection layer may be removed after the tilted I² process is performed.

In some embodiments, the first doping region 835I may not be formed in the middle electrode 835 by controlling process conditions such as the tilted angle. Accordingly, only the second and third doping regions 845I and 855I may be formed in the insulation layer 845 and in the upper electrode 855, respectively.

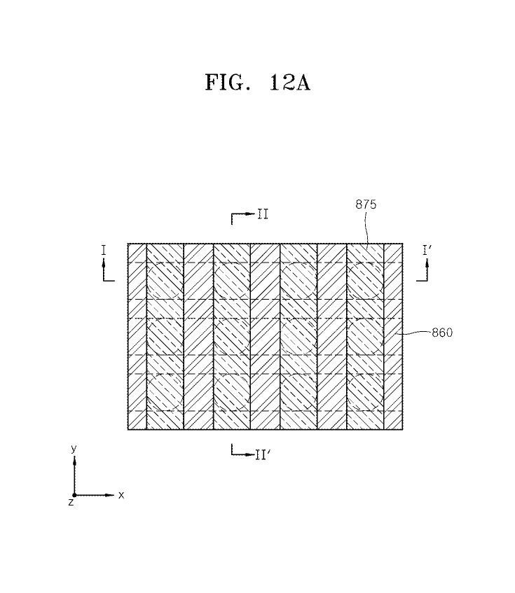

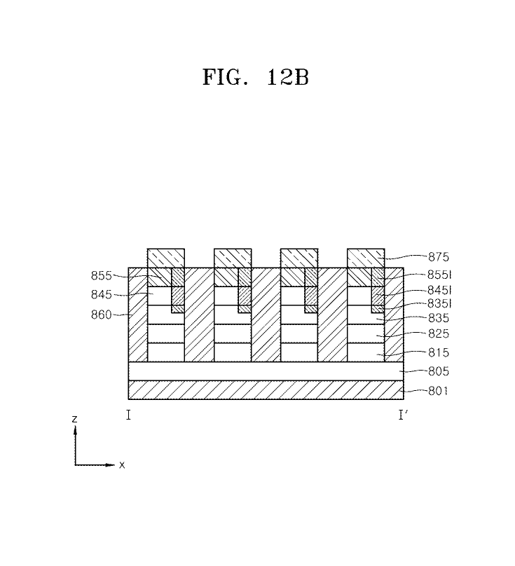

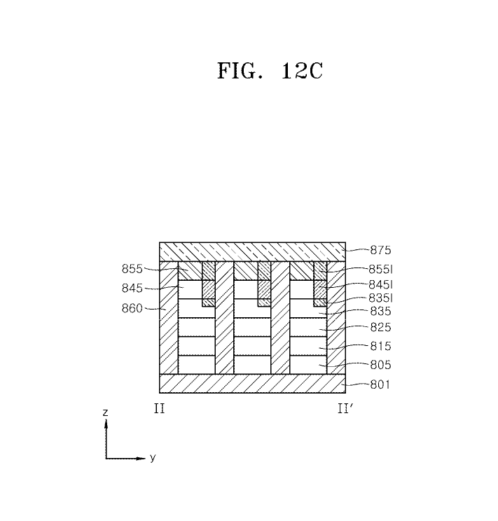

Referring to FIGS. 12A, 12B, and 12C, a first interlayer insulation layer 860 may be formed to fill spaces between the pillar-shaped structures 80. Subsequently, a plurality of upper conductive lines 875 may be formed on the upper electrodes 855 and the first interlayer insulation layer 860. The upper conductive lines 875 may be formed to be nonparallel with the lower conductive lines 805.

In an embodiment, a process for forming the upper conductive lines 875 may include forming a conductive material layer on the upper electrodes 855 and the first interlayer insulation layer 860 using a deposition process, and patterning the conductive material layer using a lithography process and an etch process. The upper conductive lines 875 may be formed to include a metal material, a conductive metal nitride material, a conductive metal oxide material, or the like.

An ReRAM device may be manufactured by applying the above processes according to an embodiment. According to this embodiment, when manufacturing a resistive memory device that includes a selection element and a variable resistive element, a size of a threshold switching operation region of the selection element can be changed without performing an additional patterning process for the pillar-shaped structures. Specifically, the size of the threshold switching operation region of the selection element can be reduced, without reducing the size of an operation region of the variable resistive element.

Meanwhile, the ReRAM device may be formed to include the lower conductive lines 805, and the upper conductive lines 875 which are nonparallel with the lower conductive lines 805. In addition, the ReRAM device may be formed to include the pillar-shaped structures 80 respectively located at cross points of the lower conductive lines 805 and the upper conductive lines 875, and each of the pillar-shaped structures 80 may be formed to include a variable resistive element and a selection element which are stacked. The variable resistive element may be formed to include the lower electrode 815, the resistive memory layer 825, and the middle electrode 835. The selection element may be formed to include the middle electrode 835 having the first doping region 835I, the insulation layer 845 having the second doping region 845I (or the threshold switching operation region), and the upper electrode 855 having the third doping region 855I.

In other embodiments, the middle electrode 835 of the selection element may not include the first doping region 835I. That is, the selection element may include only the threshold switching operation region 845I and the third doping region 855I that are formed in the insulation layer 845 and in the upper electrode 855, respectively.

In other embodiments, the upper electrode 855 of the selection element may not include the third doping region 855I. That is, the selection element may include only the first doping region 835I and the threshold switching operation region 845I that are formed in the middle electrode layer 835 and in the insulation layer 845, respectively.

The dopants injected in the first doping region 835I and the third doping region 855I may increase an energy barrier height at an interface of the first doping region 835I with the insulation layer 845 and an energy barrier height at an interface of the third doping region 855I with the insulation layer 845, respectively, and thereby reducing an off-current of the selection element.

The embodiments of the present disclosure have been disclosed above for illustrative purposes. Those of ordinary skill in the art will appreciate that various modifications, additions and substitutions are possible, without departing from the scope and spirit of the inventive concept as disclosed in the accompanying claims.

What is claimed is:

1. A method of manufacturing a switching element, the method comprising:
forming a pillar-shaped structure including a first electrode, an insulation layer, and a second electrode over a substrate;
performing a dopant injection process to form a first doping region in the insulation layer; and
performing the dopant injection process to form a second doping region in the first electrode, to form a third doping region in the second electrode, or both,
wherein the first and second doping regions form a first interface therebetween, and the first and third doping regions form a second interface therebetween, and wherein the first doping region corresponds to a region in which a threshold switching operation is performed.

2. The method of claim 1, wherein the dopant injection process comprises forming each of the first, second, and third doping regions in a sidewall portion of the pillar-shaped structure.

3. The method of claim 1, wherein the pillar-shaped structure is a plurality of pillar-shaped structures, and
wherein forming the pillar-shaped structure comprises:
sequentially forming a first electrode layer, an insulation material layer, and a second electrode layer over the substrate; and
patterning the second electrode layer, the insulation material layer, and the first electrode layer to form the plurality of pillar-shaped structures arranged in a plurality of rows and columns.

4. The method of claim 1, wherein the dopant injection process is performed using a tilted ion implantation (I²) process to inject dopants into a sidewall portion of the pillar-shaped structure.

5. The method of claim 4, wherein the dopant injection process is performed such that a distribution of the injected dopants has an annular shape extending from an outer surface of the pillar-shaped structure toward a central axis of the pillar-shaped structure and having a predetermined thickness in a radial direction of the pillar-shaped structure.

6. The method of claim 4, wherein the dopant injection process is performed such that the injected dopants are distributed in an inner portion of the pillar-shaped structure, the inner portion being spaced apart from an outer surface of the pillar-shaped structure.

7. The method of claim 1, wherein the insulation layer comprises one selected from the group consisting of a silicon oxide material, a silicon nitride material, a metal oxide material, a metal nitride material, and a combination thereof.

8. The method of claim 7, wherein the dopant injection process comprises injecting dopants using an ion implantation (I²) process, the injected dopants including at least one selected from the group consisting of aluminum (Al), lanthanum (La), niobium (Nb), vanadium (V), tantalum (Ta), tungsten (W), chrome (Cr), molybdenum (Mo), titanium (Ti), copper (Cu), zirconium (Zr), and hafnium (Hf).

9. A switching element comprising:
a pillar-shaped structure including a first electrode, an insulation layer, and a second electrode;
a first doping region disposed in the insulation layer; and
at least one of a second doping region disposed in the first electrode and a third doping region disposed in the second electrode,
wherein a first interface is disposed between the first and second doping regions, and a second interface is disposed between the first and third doping regions, and
wherein the first doping region corresponds to a region in which a threshold switching operation is performed.

10. The switching element of claim 9, wherein each of the first, second, and third doping regions is disposed in a sidewall portion of the pillar-shaped structure.

11. The switching element of claim 9, wherein the first doping region has an annular shape extending from an outer surface of the pillar-shaped structure toward a central axis of the pillar-shaped structure and having a predetermined thickness in a radial direction of the pillar-shaped structure.

12. The switching element of claim 9, wherein the first doping region is disposed in an inner portion of the pillar-shaped structure, the inner portion being spaced apart from an outer surface of the pillar-shaped structure.

13. The switching element of claim 9, wherein the insulation layer includes one selected from the group consisting of a silicon oxide material, a silicon nitride material, a metal oxide material, a metal nitride material, and a combination thereof.

14. The switching element of claim 13, wherein dopants in the first and second doping regions, in the first and third doping regions, or in the first, second, and third doping regions, comprise at least one selected from the group consisting of aluminum (Al), lanthanum (La), niobium (Nb), vanadium (V), tantalum (Ta), tungsten (W), chrome (Cr), molybdenum (Mo), titanium (Ti), copper (Cu), zirconium (Zr), and hafnium (Hf).
